(19) United States
(12) Patent Application Publication
(10) Pub. No.: US 2026/0242979 A1
(43) Pub. Date: Aug. 20, 2026

(54) GALLIUM ARSENIDE SINGLE CRYSTAL SUBSTRATE, METHOD OF PRODUCING GALLIUM ARSENIDE SINGLE CRYSTAL, AND METHOD OF PRODUCING GALLIUM ARSENIDE SINGLE CRYSTAL SUBSTRATE

(71) Applicant: Sumitomo Electric Industries, Ltd., Osaka (JP)

(72) Inventors: Yukio ISHIKAWA, Osaka (JP); Hidetoshi TAKAYAMA, Osaka (JP); Kazuaki KOUNOIKE, Osaka (JP)

(73) Assignee: Sumitomo Electric Industries, Ltd., Osaka (JP)

(21) Appl. No.: 19/537,628

(22) Filed: Feb. 12, 2026

(30) Foreign Application Priority Data
Feb. 17, 2025 (JP) 2025-023296

(51) Int. Cl. C30B 29/40; C30B 11/02; C30B 11/06

(52) U.S. Cl. CPC C30B 29/403; C30B 11/02; C30B 11/065

(57) ABSTRACT

A gallium arsenide single crystal substrate has electron-donating type conductivity. The gallium arsenide single crystal substrate has main surfaces each having a circular shape. The gallium arsenide single crystal substrate includes an electron-donating type dopant. A value of an absorption coefficient of the gallium arsenide single crystal substrate for infrared light having a wavelength of 1 micron as obtained by performing measurement after performing electron beam irradiation on at least one of the main surfaces under a condition of an acceleration voltage of 2 MeV and an irradiation dose of 150 kGy is 95% or more and 100% or less of a value of an absorption coefficient of the gallium arsenide single crystal substrate for infrared light having a wavelength of 1 micron as obtained by performing measurement before performing the electron beam irradiation.

### CROSS REFERENCE TO RELATED APPLICATIONS

This nonprovisional application is based on Japanese Patent Application No. 2025-023296 filed on Feb. 17, 2025 with the Japan Patent Office, the entire contents of which are hereby incorporated by reference.

### BACKGROUND OF THE INVENTION

### Field of the Invention

The present disclosure relates to a gallium arsenide single crystal substrate, a method of producing a gallium arsenide single crystal, and a method of producing a gallium arsenide single crystal substrate.

### Description of the Background Art

Japanese National Patent Publication No. 2011-527280 (PTL 1) discloses a method of producing a gallium arsenide single crystal substrate (hereinafter, also referred to as “GaAs single crystal substrate”) having a small light absorption coefficient in a near-infrared region. WO 2012/160781 (PTL 2) discloses a GaAs single crystal substrate having a high carrier concentration and high crystallinity. Japanese Patent Laying-Open No. 2004-115339 (PTL 3) relates to production of a gallium arsenide single crystal (hereinafter, also referred to as “GaAs single crystal”), to which silicon (Si) is added as an impurity, by a vertical boat method, and discloses a method of producing a GaAs single crystal in which occurrence of dislocation due to precipitation of boron arsenide is prevented.

### SUMMARY OF THE INVENTION

A gallium arsenide single crystal substrate according to the present disclosure is a gallium arsenide single crystal substrate having electron-donating type conductivity. The gallium arsenide single crystal substrate has main surfaces each having a circular shape. The gallium arsenide single crystal substrate includes an electron-donating type dopant. A value of an absorption coefficient of the gallium arsenide single crystal substrate for infrared light having a wavelength of 1 micron as obtained by performing measurement after performing electron beam irradiation on at least one of the main surfaces under a condition of an acceleration voltage of 2 MeV and an irradiation dose of 150 kGy is 95% or more and 100% or less of a value of an absorption coefficient of the gallium arsenide single crystal substrate for infrared light having a wavelength of 1 micron as obtained by performing measurement before performing the electron beam irradiation.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an explanatory diagram illustrating a GaAs single crystal substrate according to the present embodiment as well as a measurement target location (measurement target region) for measuring an absorption coefficient of the substrate for infrared light having a wavelength of 1 micron.

FIG. 2 is an explanatory diagram illustrating a Hall measurement sample produced using a central portion of the substrate in order to measure a carrier concentration in the GaAs single crystal substrate according to the present embodiment.

FIG. 3 is a flowchart showing an overview of each of a method of producing a GaAs single crystal and a method of producing the GaAs single crystal substrate according to the present embodiment.

FIG. 4 is an explanatory diagram illustrating a step of growing the GaAs single crystal using a single crystal production apparatus with regard to the method of producing the GaAs single crystal according to the embodiment.

### DESCRIPTION OF THE PREFERRED EMBODIMENTS

When the use of an optical device or the like in a space environment is assumed, the optical device may be required to have reliability so as to operate stably under exposure to space radiation. For example, in NanotechJapan Bulletin Vol. 13, No. 1, 2020, P1-8 (NPL 1), deterioration of a gallium nitride-based device due to an electron beam of 2 MeV caused by solar flare is evaluated. Phys. Rev. B, Vol. 52, No. 15, (1995), 10932 (NPL 2) evaluates introduction of point defects and state of recovery when an electron beam of 1.5 MeV is applied to a Si-doped GaAs single crystal substrate produced using a horizontal Bridgman method. As the substrate applied to the optical device, a GaAs single crystal substrate having an excellent feature from the viewpoint of reliability has not been realized yet. Development of the GaAs single crystal substrate satisfying the above requirement has been desired.

In view of the above actual circumstance, an object of the present disclosure is to provide a GaAs single crystal substrate, a method of producing a GaAs single crystal, and a method of producing the GaAs single crystal substrate so as to attain reduced deterioration of performance due to exposure to radiation or the like.

First, an overview of embodiments of the present disclosure will be described. As a result of diligent studies, the present inventors have reached the present disclosure by which the above problem can be solved. Specifically, in a GaAs single crystal substrate having electron-donating type conductivity (hereinafter, also referred to as an “n type”), attention has been paid to attaining a small fluctuation of an activation ratio of an n type dopant before and after exposure to radiation. With the attention being paid thereto, the GaAs single crystal was produced using a vertical boat method by controlling an amount of addition of the n type dopant, a partial pressure of arsenic (As) in a crucible, or the like such that the activation ratio of the n type dopant in the GaAs single crystal becomes about 50%. In this case, it has been found that in a GaAs single crystal substrate obtained from the GaAs single crystal, fluctuation of an absorption coefficient thereof for infrared light having a wavelength of 1 micron before and after electron beam irradiation under a predetermined condition is small. In this way, a GaAs single crystal substrate in which deterioration of performance due to exposure to radiation can be reduced has been conceived, thereby completing the present disclosure.

Next, embodiments of the present disclosure will be listed and described. [1] A GaAs single crystal substrate according to one embodiment of the present disclosure is a GaAs single crystal substrate having n type conductivity. The GaAs single crystal substrate has main surfaces each having a circular shape. The GaAs single crystal substrate includes an n type dopant. A value of an absorption coefficient of the GaAs single crystal substrate for infrared light having a wavelength of 1 micron as obtained by performing measurement after performing electron beam irradiation on at least one of the main surfaces under a condition of an acceleration voltage of 2 MeV and an irradiation dose of 150 kGy is 95% or more and 100% or less of a value of an absorption coefficient of the GaAs single crystal substrate for infrared light having a wavelength of 1 micron as obtained by performing measurement before In the GaAs single crystal substrate having performing the electron beam irradiation, such a feature, deterioration of performance due to exposure to radiation or the like can be reduced. Therefore, the GaAs single crystal substrate can be a substrate of an optical device assumed to be used in a space environment.

[2] In the GaAs single crystal substrate according to [1], the GaAs single crystal substrate may have a carrier concentration of 3.5×10¹⁸ cm⁻³ or more and 5.0×10¹⁸ cm⁻³ or less. The GaAs single crystal substrate may have an activation ratio of the n type dopant of 40% or more and 60% or less. In this case, the GaAs single crystal substrate in which deterioration of performance due to exposure to radiation or the like can be reduced can be provided with a high yield.

[3] In the GaAs single crystal substrate according to [2], the GaAs single crystal substrate may have an activation ratio of the n type dopant of 45% or more and 55% or less. In this case, the GaAs single crystal substrate in which deterioration of performance due to exposure to radiation or the like can be reduced can be provided with a high yield.

[4] In the GaAs single crystal substrate according to any one of [1] to [3], the GaAs single crystal substrate may have an atomic concentration of the n type dopant of 5.8×10¹⁸ cm⁻³ or more and 1.3×10¹⁹ cm⁻³ or less. In this case, an excessive decrease in the activation ratio of the n type dopant can be prevented.

[5] In the GaAs single crystal substrate according to any one of [1] to [4], the GaAs single crystal substrate may include boron (B). The GaAs single crystal substrate may have an atomic concentration of the B of 4.0×10¹⁸ cm⁻³ or more and 6.0×10¹⁸ cm⁻³ or less. In this case, the GaAs single crystal substrate in which deterioration of performance due to exposure to radiation or the like can be reduced can be provided with a high yield.

[6] In the GaAs single crystal substrate according to any one of [1] to [5], the value of the absorption coefficient of the GaAs single crystal substrate for the infrared light having the wavelength of 1 micron as obtained by performing the measurement before performing the electron beam irradiation may be 3.6 cm⁻¹ or more. In this case, the GaAs single crystal substrate having an excellent optical property can be provided.

[7] In the GaAs single crystal substrate according to any one of [1] to [6], the n type dopant may be at least one selected from a group consisting of silicon (Si), tellurium (Te), and tin (Sn). In this case, the GaAs single crystal substrate in which deterioration of performance due to exposure to radiation or the like can be reduced can be provided with a high yield.

[8] In the GaAs single crystal substrate according to any one of [1] to [7], the GaAs single crystal substrate may have a dislocation density of 1000 cm⁻² or less. In this case, the GaAs single crystal substrate having an excellent optical property can be provided.

[9] In the GaAs single crystal substrate according to [8], the GaAs single crystal substrate may at least include Si as the n type dopant. The GaAs single crystal substrate may have an atomic concentration of the Si of 2.0×10¹⁸ cm⁻³ or more. The GaAs single crystal substrate may have a dislocation density of 100 cm⁻² or less. In this case, the GaAs single crystal substrate having an excellent optical property can be provided.

[10] A method of producing a GaAs single crystal according to one embodiment of the present disclosure is a method of producing a GaAs single crystal having n type conductivity using a vertical boat method. The production method includes: preparing a single crystal growth apparatus at least including a crucible having a cylindrical shape and a heating apparatus disposed to surround an outer periphery of the crucible; accommodating a seed crystal at a bottom portion of the crucible and accommodating an n type dopant, boron oxide (B₂O₃), metal arsenic, and a GaAs polycrystal in a form of a bulk or powder above the seed crystal in the crucible, the seed crystal being composed of the GaAs single crystal; heating the crucible using the heating apparatus to sublimate the metal arsenic, melt the B₂O₃ into a B₂O₃ melt, melt a part of the seed crystal and the GaAs polycrystal into a GaAs melt, obtain a first melt in which the n type dopant is dissolved in the GaAs melt, and bring the first melt into contact with a remainder of the seed crystal; and obtaining the GaAs single crystal by growing a crystal from the first melt on the remainder of the seed crystal. The single crystal growth apparatus includes a branch pipe portion that controls a partial pressure of arsenic in the crucible. In the obtaining the GaAs single crystal, an end surface of the first melt not in contact with the remainder of the seed crystal is covered with the B₂O₃ melt by 10 area % or more and 50 area % or less. In the obtaining the GaAs single crystal, the GaAs in the first melt has an atomic ratio of As to gallium (Ga) greater than 1. According to the production method having such a feature, the GaAs single crystal in which deterioration of performance due to exposure to radiation or the like is reduced can be obtained.

[11] In the method of producing the GaAs single crystal according to [10], in the obtaining the GaAs single crystal, the crucible may not be rotated and the first melt may not be stirred. In this case, the GaAs single crystal having an activation ratio of the n type dopant of about 50% may be obtained.

[12] A method of producing a GaAs single crystal substrate according to one embodiment of the present disclosure includes obtaining a GaAs single crystal substrate having a main surface having a circular shape by processing the GaAs single crystal obtained by the method of producing the GaAs single crystal according to or [11]. According to the production method having such a feature, deterioration of performance due to exposure to radiation or the like is reduced, thereby obtaining the GaAs single crystal substrate suitable as a substrate of an optical device assumed to be used in a space environment.

Hereinafter, one embodiment (hereinafter, also referred to as “the present embodiment”) according to the present disclosure will be described more in detail, but the present disclosure is not limited thereto. Although explanation may be made in the description below with reference to figures, the same or corresponding elements will be denoted by the same reference characters in the present specification and figures, and the same explanation therefor will not be described repeatedly. Moreover, in each of the figures, the scale of each component is appropriately adjusted in order to facilitate understanding, and the scale of each component shown in each of the figures does not necessarily coincide with the actual scale of the component.

In the present specification, the expression “A to B” means the lower and upper limits of a range (i.e., A or more and B or less), and when no unit is indicated for A and a unit is indicated only for B, the unit of A and the unit of B are the same. Moreover, when a compound or the like is expressed by a chemical formula in the present specification and an atomic ratio is not particularly limited, the compound includes all the conventionally known atomic ratios, and the atomic ratio should not be necessarily limited only to one in the stoichiometric range. For example, when “GaAs” is described, a ratio of atoms in the GaAs is not limited to Ga:As=1:1 unless stated particularly, and include all the conventionally known atomic ratios. The same also applies to description of a compound other than the “GaAs”.

In the present specification, a “main surface” of the GaAs single crystal substrate means each of two circular surfaces of the substrate. When at least one of the two surfaces of the GaAs single crystal substrate satisfies the scope of claims with regard to the present disclosure, the GaAs single crystal substrate falls within the scope of the present invention. An epitaxial film may be disposed on the “main surface” of the GaAs single crystal substrate. Moreover, in the present specification, the term “plane” used in the expression “in-plane” or “in the plane” means the “main surface”. Further, when it is described that the diameter of the GaAs single crystal substrate is “70 mm”, it means that the diameter is about 70 mm (about 70 to 76.5 mm) or 3 inches. When it is described that the diameter is “100 mm”, it means that the diameter is about 100 mm (about 95 to 105 mm) or 4 inches. When it is described that the diameter is “150 mm”, it means that the diameter is about 150 mm (about 145 to 155 mm) or 6 inches. When it is described that the diameter is “210 mm”, it means that the diameter is about 210 mm (about 195 to 210 mm) or 8 inches. The diameter is measured by using a conventionally known outer diameter measurement device such as a caliper.

In the present specification, a “dislocation” is a type of crystal defect, and refers to a defect (line defect) in which atomic displacement is generated in the form of a line in a crystal lattice. The “dislocation” is confirmed as a dislocation line generated, when slippage (displacement) has occurred in a certain region in the crystal, at a boundary between the region in which the slippage has occurred and a region in which no slippage has occurred. It should be noted that the magnitude and direction of the slippage involved in the “dislocation” are represented by a Burgers vector.

In the present specification, a “yield” means a ratio of a mass evaluated to be possibly a conforming product as the substrate when processed into a GaAs single crystal substrate in a mass of an ingot composed of a GaAs single crystal grown by crystal growth in the crucible. It should be noted that it is evaluated that as the “yield” is better (indicates a larger value), a larger number of GaAs single crystal substrates can be obtained from the GaAs single crystal grown in the crucible.

Regarding a crystallographic description in the present specification, an individual orientation is represented by [ ], a group orientation is represented by < >, an individual plane is represented by ( ) and a group plane is represented by { }. Moreover, a negative crystallographic index is normally expressed by adding “-(bar)” above a numeral, but in the present specification, a negative sign is put before the numeral.

### [GaAs Single Crystal Substrate]

A GaAs single crystal substrate according to the present embodiment is a GaAs single crystal substrate having n type conductivity. The GaAs single crystal substrate has main surfaces each having a circular shape. The GaAs single crystal substrate includes an n type dopant. A value of an absorption coefficient of the GaAs single crystal substrate for infrared light having a wavelength of 1 micron as obtained by performing measurement after performing electron beam irradiation on at least one of the main surfaces under a condition of an acceleration voltage of 2 MeV and an irradiation dose of 150 kGy is 95% or more and 100% or less of a value of an absorption coefficient of the GaAs single crystal substrate for infrared light having a wavelength of 1 micron as obtained by performing measurement before performing the electron beam irradiation. Since a ratio of fluctuation of the absorption coefficient for the infrared light before and after the electron beam irradiation is small in the GaAs single crystal substrate having such a feature, deterioration of performance due to exposure to radiation or the like can be reduced. Therefore, the GaAs single crystal substrate can be a substrate of an optical device assumed to be used in a space environment.

A reason why the deterioration of performance due to exposure to radiation or the like can be reduced in the GaAs single crystal substrate according to the present embodiment is based on the following feature. That is, deterioration of performance of a single crystal substrate using, as its material, a so-called compound semiconductor single crystal or the like in a space environment is generally caused by, for example, collapse of a structure (for example, a crystal lattice structure) of the material of the substrate due to knock-on of atoms caused when the substrate is irradiated with space radiation. Generally, a compound semiconductor exhibits n type or p type depending on a position of occupation of an impurity element called a dopant in a crystal or the like; however, when the knock-on of atoms is caused by the irradiation with radiation, the position of occupation of the dopant in the crystal may be changed to adversely affect various physical properties such as an electrical property. Therefore, this means that even when the substrate undergoes an event such as exposure to radiation, the deterioration of the substrate due to the exposure to radiation or the like is reduced if the change of the position of occupation in the substrate before and after the event is reduced.

The GaAs single crystal substrate according to the present embodiment may have a carrier concentration and an atomic concentration of an n type dopant, each of which has a feature described below. The GaAs single crystal substrate may have a predetermined atomic concentration of an impurity element other than the n type dopant, such as B. Further, as stated clearly in a production method described below, a GaAs single crystal used for the GaAs single crystal substrate is obtained by using a vertical boat method to perform crystal growth through an operation of controlling a partial pressure of As in the crucible at the same time at which an upper part of the melt in the crucible is partially covered with B₂O₃. In that case, the activation ratio of the n type dopant can be about 50% in the GaAs single crystal substrate obtained by processing the GaAs single crystal.

When the activation ratio of the n type dopant is about 50% in the GaAs single crystal substrate, an amount of fluctuation of the activation ratio due to the knock-on of atoms in response to exposure to radiation in the GaAs single crystal substrate is smaller than that in a GaAs single crystal substrate in which the activation ratio of an n type dopant is close to 100%. For example, when the main surface of the GaAs single crystal substrate is irradiated with an electron beam under a condition of an acceleration voltage of 2 MeV and an irradiation dose of 150 kGy, the ratio of fluctuation of the absorption coefficient thereof for infrared light having a wavelength of 1 micron before and after the irradiation is small, i.e., 5% or less. That is, the deterioration of the GaAs single crystal substrate due to exposure to radiation or the like can be reduced in the GaAs single crystal substrate in which the activation ratio of the n type dopant is close to 50%. In view of the above, the deterioration of performance due to exposure to radiation or the like can be reduced in the GaAs single crystal substrate according to the present embodiment, and the GaAs single crystal substrate can be therefore a substrate of an optical device assumed to be used in a space environment.

### <Main Surface>

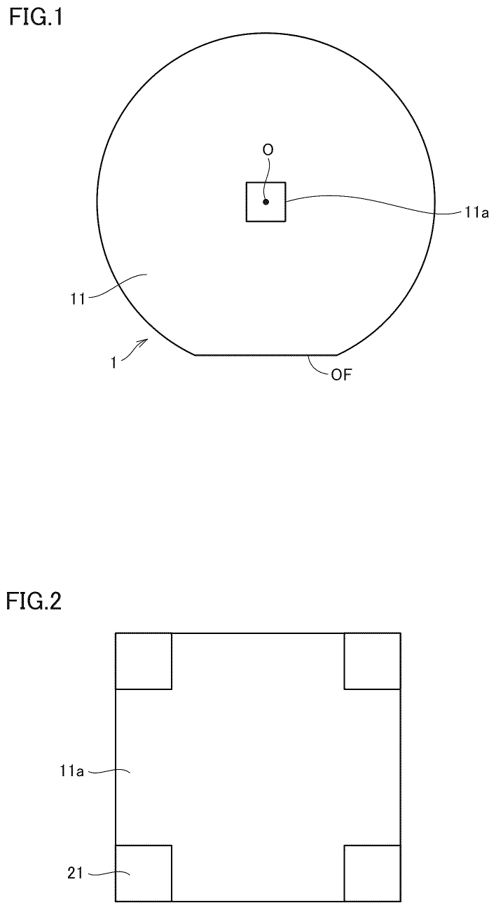

FIG. 1 is an explanatory diagram illustrating the GaAs single crystal substrate according to the present embodiment as well as a measurement target location (measurement target region) for measuring the absorption coefficient of the substrate for the infrared light having a wavelength of 1 micron. As shown in FIG. 1, a GaAs single crystal substrate 1 has main surfaces 11 each having a circular shape. In the present specification, the “circular shape” representing the shape of each main surface 11 includes not only a geometric circular shape but also a shape when main surface 11 does not form the geometric circular shape due to formation of at least one of a notch, an orientation flat (hereinafter, also referred to as “OF”), or an index flat (hereinafter, also referred to as “IF”) in an outer periphery of main surface 11. Here, the “shape when the main surface does not form the geometric circular shape” means a shape when the length of a line segment extending from any point on the notch, OF, and IF to center O of main surface 11 is short among line segments each extending from any point on the outer periphery of main surface 11 to center O of main surface 11. Further, the “shape when the main surface does not form the geometric circular shape” also includes a shape when the lengths of all the line segments each extending from any point on the outer periphery of main surface 11 to center O of main surface 11 are not necessarily the same due to the shape of a GaAs single crystal serving as a source material for GaAs single crystal substrate 1. In this case, center O of main surface 11 refers to the position of the center of gravity. The diameter of GaAs single crystal substrate 1 refers to the length of the longest line segment among the line segments each extending from any point on the outer periphery of GaAs single crystal substrate 1 to another point on the outer periphery via center O of main surface 11.

### (Off Angle)

Main surface 11 may be a {100} plane of the GaAs single crystal. For example, main surface 11 of GaAs single crystal substrate 1 shown in FIG. 1 may be a {100} plane. Further, main surface 11 of GaAs single crystal substrate 1 may be a plane having an off angle of more than 0° and 15° or less with respect to the {100} plane.

In each of a case where main surface 11 of GaAs single crystal substrate 1 is the {100} plane and a case where main surface 11 has the off angle of more than 0° and 15° or less with respect to the {100} plane, main surface 11 of GaAs single crystal substrate 1 is a plane having an orientation allowing for excellent electrical property and optical property. Thus, in the present embodiment, GaAs single crystal substrate 1 having, as main surface 11, a plane that facilitates processing of an element having a rectangular or square shape by using cleavage of the {100} plane of the GaAs is provided, and GaAs single crystal substrate 1 can be therefore applied to an optical device. In GaAs single crystal substrate 1, main surface 11 may be the {100} plane, or main surface 11 may be a plane having an off angle of more than 0° and 10° or less with respect to the {100} plane. In GaAs single crystal substrate 1, main surface 11 may be the {100} plane, or main surface 11 may be a plane having an off angle of more than 0° and 5° or less with respect to the {100} plane.

### <Diameter>

The diameter of GaAs single crystal substrate 1 may be 95 mm or more and 205 mm or less. Specifically, GaAs single crystal substrate 1 having the diameter of 95 mm or more and 205 mm or less may have a diameter of 100 mm, 150 mm, or 200 mm, in other words, may have a diameter of 4 inches, 6 inches, or 8 inches. Thus, in GaAs single crystal substrate 1 having the large diameter of 95 mm or more and 205 mm or less, the deterioration of performance due to exposure to radiation or the like can be reduced. It should be noted that the diameter of GaAs single crystal substrate 1 is measured by using a conventionally known outer diameter measurement device such as a caliper as described above.

### <n Type Conductivity>

GaAs single crystal substrate 1 has the n type conductivity as described above. GaAs single crystal substrate 1 includes the n type dopant. That is, since GaAs single crystal substrate 1 includes the n type dopant, GaAs single crystal substrate 1 exhibits the n type conductivity as described above. When an optical device is formed by, for example, layering an epitaxial layer on main surface 11 of GaAs single crystal substrate 1, a light emitting layer (active layer) may be directly formed on main surface 11, and an n type cladding layer, a DFB (Distributed Feedback) layer, or a DBR (Distributed Bragg Reflector) layer may be formed thereon because the conductivity type thereof is the n type.

### (n Type Dopant)

GaAs single crystal substrate 1 includes the n type dopant as described above. The n type dopant may be at least one selected from a group consisting of Si, Te, and Sn.
For example, when the n type dopant included in GaAs single crystal substrate 1 is Si, the Si can be introduced into both a Ga site in which Ga can be present and an As site in which As can be present within the GaAs crystal lattice structure in GaAs single crystal substrate 1. Therefore, by adjusting the number of Si atoms present in the Ga site and the number of Si atoms present in the As site, the activation ratio of the n type dopant in GaAs single crystal substrate 1 can be controlled. GaAs single crystal substrate 1 may include two types of elements such as Si and Te, Si and Sn, or Te and Sn as the n type dopant, or may include three types of elements such as Si, Te, and Sn.

### (Atomic Concentration of n Type Dopant)

GaAs single crystal substrate 1 may have an atomic concentration of the n type dopant of 5.8×10¹⁸ cm⁻³ or more and 1.3×10¹⁹ cm⁻³ or less. GaAs single crystal substrate 1 may have an atomic concentration of the n type dopant of 6.0×10¹⁸ cm⁻³ or more and 1.15×10¹⁹ cm⁻³ or less, or may have an atomic concentration of the n type dopant of 7.0×10¹⁸ cm⁻³ or more and 1.0×10¹⁹ cm⁻³ or less. When the atomic concentration of the n type dopant is in the above-described range, the activation ratio of the n type dopant can be prevented from being decreased excessively in GaAs single crystal substrate 1. When the activation ratio of the n type dopant is decreased excessively in GaAs single crystal substrate 1, it becomes difficult to provide GaAs single crystal substrate 1 as a substrate for forming a high-quality optical device. When the two or more types of n type dopants are included in GaAs single crystal substrate 1, the “atomic concentration of the n type dopant” described above means the total atomic concentration of the two or more types of n type dopants.

The type and atomic concentration of the n type dopant included in GaAs single crystal substrate 1 are measured by using glow discharge mass spectrometry (GDMS). The GDMS refers to a method in which glow discharge plasma is generated using an analysis sample as a cathode under a high-purity argon atmosphere and a surface of the analysis sample is sputtered in the plasma so as to measure an ionized constituent element in the analysis sample using a mass spectrometer. Thus, an impurity element other than Ga and As in the GaAs single crystal substrate, such as the n type dopant, is qualitatively and quantitatively determined.

The GDMS is performed in the following manner, for example. First, GaAs single crystal substrate 1 is obtained by the production method described later. Further, GaAs single crystal substrate 1 is, for example, cleaved to prepare an analysis sample having a strip shape of 2 mm square with a length of 20 mm. The analysis sample is then placed in a sample placement portion accompanied with the GDMS apparatus. Here, cleaning may be performed onto the sample placement portion in a usual manner for the purpose of preventing introduction of a foreign matter and removing a foreign matter, and pre-sputtering may be performed for 60 minutes.

Next, the GDMS is performed onto the analysis sample under the following condition. It should be noted that the semi-quantitative value of the element serving as the n type dopant in the analysis sample is calculated by correcting an ion intensity ratio of the Ga and the As using a relative sensitivity factor (RSF). It should be noted that as the relative sensitivity factor, a value in software accompanied with the below-described apparatus is used. For example, a measurement condition in the GDMS for GaAs single crystal substrate 1 is as follows.
Apparatus: glow discharge mass spectrometer (product name (item number): VG-9000 provided by VG Elemental)
Ion source: pin-shaped cell (cooled by liquid nitrogen during the analysis)
Discharging area: diameter of 10 mm
Discharging gas: high-purity argon (6N grade)
Discharging condition: 2 mA, 1 kV (constant current mode)
Detector: Faraday cup and multiplier
Mass resolution: m/Δm of 4000 or more (high-resolution mode)

### <Carrier Concentration>

GaAs single crystal substrate 1 may have a carrier concentration of 3.5×10¹⁸ cm⁻³ or more and 5.0×10¹⁸ cm⁻³ or less. GaAs single crystal substrate 1 may have the carrier concentration of 3.6×10¹⁸ cm⁻³ or more and 4.9×10¹⁸ cm⁻³ or less, or may have the carrier concentration of 3.7×10¹⁸ cm⁻³ or more and 4.8×10¹⁸ cm⁻³ or less. When the carrier concentration is in the above-described range, the activation ratio of the n type dopant in GaAs single crystal substrate 1 can be readily controlled to be about 50% in relation with the atomic concentration of the n type dopant.

The carrier concentration of GaAs single crystal substrate 1 is measured by Hall measurement at 25° C. by the Van der Pauw method. A procedure for determining the carrier concentration will be specifically described with reference to FIGS. 1 and 2. First, as shown in FIG. 1, for example, one GaAs single crystal substrate 1 serving as a measurement target is obtained by applying a conventionally known processing method onto a GaAs single crystal obtained based on the below-described production method. A rectangular cut piece 11a (having a thickness of, for example, 650 μm) having a size of 4 mm in length×4 mm in width with its center (for example, the center of main surface 11) as center O is produced from the central portion of the one GaAs single crystal substrate 1. Next, as shown in FIG. 2, electrodes 21 each composed of an alloy including gold, nickel and germanium are formed at four corners of rectangular cut piece 11a (measurement target surface), thereby obtaining a Hall measurement sample. Here, the shape of each electrode 21 is not limited to the rectangular shape shown in the figure, and may be a fan shape or a circular shape. The carrier concentration is determined by applying the Hall measurement using the Van der Pauw method onto rectangular cut piece 11a including such electrode 21 under an atmosphere of 25° C. It should be noted that in the present specification, the carrier concentration obtained based on the rectangular cut piece serving as the measurement target is defined as the carrier concentration of the GaAs single crystal substrate.

### <Activation Ratio of n Type Dopant>

GaAs single crystal substrate 1 may have the activation ratio of the n type dopant of 40% or more and 60% or less. GaAs single crystal substrate 1 may have the activation ratio of the n type dopant of 45% or more and 55% or less. In this case, GaAs single crystal substrate 1 in which the deterioration of performance due to exposure to radiation or the like can be reduced due to the above reason can be provided with a high yield.

The activation ratio of the n type dopant is determined from the ratio of the above-described carrier concentration of GaAs single crystal substrate 1 and the atomic concentration of the n type dopant, and is expressed in percentage. Specifically, the activation ratio of the n type dopant is determined by substituting the carrier concentration of GaAs single crystal substrate 1 and the atomic concentration of the n type dopant into the following formula: (the activation ratio of the n type dopant, %)=(the carrier concentration)/(the atomic concentration of the n type dopant)× 100.

### <Boron (B)>

GaAs single crystal substrate 1 may include B. GaAs single crystal substrate 1 may have an atomic concentration of the B of 4.0×10¹⁸ cm⁻³ or more and 6.0×10¹⁸ cm⁻³ or less. Since the B is introduced into the Ga site in the crystal lattice of the GaAs single crystal, the B competes with the n type dopant to be introduced into the Ga site. Therefore, when the B is included in GaAs single crystal substrate 1 in the atomic concentration range described above, the n type dopant is facilitated to enter the As site. In this case, the B contributes to decreasing the carrier concentration in GaAs single crystal substrate 1, thereby controlling the activation ratio of the n type dopant in GaAs single crystal substrate 1.

The B is originated from a B₂O₃ melt that partially covers a first melt in which the n type dopant is dissolved in a GaAs melt in the below-described method of producing the GaAs single crystal. Since the B improves the strength of the GaAs single crystal, the B has an effect of suppressing the knock-on of atoms during exposure to radiation. However, when the atomic concentration of the B is more than 6.0×10¹⁸ cm⁻³, boron arsenide is included in GaAs single crystal substrate 1, which may adversely affect the optical property. The atomic concentration of the B is determined by a measurement method using the GDMS described above.

### <Absorption Coefficient for Infrared Light Having Wavelength of 1 Micron>

In GaAs single crystal substrate 1, the value of the absorption coefficient of GaAs single crystal substrate 1 for the infrared light having the wavelength of 1 micron (hereinafter, also referred to as “near-infrared light absorption coefficient after the electron beam irradiation”) as obtained by performing the measurement after performing the electron beam irradiation on at least one of main surfaces 11 under the condition of the acceleration voltage of 2 MeV and the irradiation dose of 150 kGy is 95% or more and 100% or less of the absorption coefficient of GaAs single crystal substrate 1 for the infrared light having the wavelength of 1 micron (hereinafter, also referred to as “near-infrared light absorption coefficient before the electron beam irradiation”) as obtained by performing the measurement before performing the electron beam irradiation. In this case, the value of the near-infrared light absorption coefficient before performing the electron beam irradiation may be 3.6 cm⁻¹ or more. The value of the near-infrared light absorption coefficient before performing the electron beam irradiation may be 4.2 cm⁻¹ or less. The value of the near-infrared light absorption coefficient after performing the electron beam irradiation may be 3.6 cm⁻¹ or more and 4.4 cm⁻¹ or less. When the value of the near-infrared light absorption coefficient before performing the electron beam irradiation is in the above-described range, light absorption by GaAs single crystal substrate 1 is suppressed in the case of, for example, an optical device which allows for passage of light through GaAs single crystal substrate 1 and is used as an optical sensor or the like, with the result that there is a possibility that an amount of grinding of the rear surface of the substrate can be reduced or a problem such as damage when grinding the rear surface can be reduced.

The absorption coefficient described above is determined by a conventionally known method in accordance with transmittance and reflectance of a substance for light as measured using an ultraviolet-visible infrared spectrophotometer or the like. However, when the transmittance and reflectance of GaAs single crystal substrate 1 for light are obtained by using the ultraviolet-visible infrared spectrophotometer or the like, occurrence of multiple reflections between the two parallel main surfaces needs to be taken into consideration, and therefore, the absorption coefficient can be determined by the following method. That is, by using the ultraviolet-visible infrared spectrophotometer and causing near-infrared light having a wavelength of 1 micron to be incident on center O of main surface 11 of GaAs single crystal substrate 1 at an angle of 85°, the transmittance and reflectance of GaAs single crystal substrate 1 for the near-infrared light are measured. Further, by substituting the numerical value of the transmittance, the numerical value of the reflectance, and the numerical value of the thickness of GaAs single crystal substrate 1 into the following formulas 1, 2, and 3, the absorption coefficient is determined together with the reflectance of GaAs single crystal substrate 1 for the near-infrared light at the time of one-time reflection.

$$R + {R ( 1 - R )}^{2} exp ( - 2 α d ) / ( 1 - r ) + {R}^{*} \qquad Formula 1$$

$${( 1 - R )}^{2} exp ( - α d ) / ( 1 - r ) = {T}^{*} \qquad Formula 2$$

$$r = {R}^{2} exp ( 2 α d ) \qquad Formula 3$$

In the above formulas 1, 2 and 3,
R* represents a reflectance in consideration of multiple reflections as measured by the ultraviolet-visible infrared spectrophotometer, and the unit of the reflectance is dimensionless.
T* represents a transmittance in consideration of multiple reflections as measured by the ultraviolet-visible infrared spectrophotometer, and the unit of the transmittance is dimensionless.
α represents the light absorption coefficient, and the unit of the light absorption coefficient is cm⁻¹.
R represents a reflectance of GaAs single crystal substrate 1 for the near-infrared light at the time of one-time reflection, and the unit of the reflectance at the time of the one-time reflection is dimensionless.
d represents the thickness of GaAs single crystal substrate 1, and the unit of the thickness is cm.

Hereinafter, a procedure for determining the absorption coefficient will be specifically described with reference to FIG. 1. First, two GaAs single crystal substrates 1 each serving as a measurement target are obtained by applying a conventionally known processing method to the GaAs single crystal obtained by the below-described production method, for example. Two rectangular cut pieces 11a (each having a thickness of 650 μm, for example) each having a size of 20 mm in length×20 mm in width and each having its center as center O of main surface 11 are produced from these two GaAs single crystal substrates 1, and are each used as a sample for measuring the absorption coefficient. Further, the center of the surface of one of the samples (location corresponding to center O of main surface 11 of GaAs single crystal substrate 1) is subjected to electron beam irradiation under a condition of an acceleration voltage of 2 MeV and an irradiation dose of 150 kGy. The electron beam is incident normal to the surface at center O.

Next, the ultraviolet-visible infrared spectrophotometer (product name (item number)): U-4000 provided by Hitachi High-Tech Corporation) and an absolute reflectance measurement unit accompanied therewith are used and near-infrared light having a wavelength of 1 micron is caused to be incident on, at an angle of 85° inclined by 5° with respect to the incidence perpendicular to main surface 11, the center of the surface of each of the sample having been subjected to the electron beam irradiation and the sample not having been subjected to the electron beam irradiation. Thus, the transmittances and reflectances of GaAs single crystal substrate 1 for the near-infrared light before and after the electron beam irradiation are measured. Each of the transmittances and the reflectances is obtained as a measurement value through multiple reflections between two parallel main surfaces 11 (i.e., front and rear surfaces) of GaAs single crystal substrate 1. Finally, the transmittance, the reflectance, and the thickness of the rectangular cut piece are substituted into the above-described formulas 1, 2, and 3 that are in consideration of the multiple reflections, and iterative numerical calculation thereof is performed, thereby determining the absorption coefficient. It should be noted that the absorption coefficient is determined together with the reflectance at the time of one-time reflection at main surface 11 of GaAs single crystal substrate 1. The above-described “reflectance at the time of one-time reflection” means a reflectance determined based on transmission and reflection for the incident near-infrared light, which first take place at main surface 11 of GaAs single crystal substrate 1. In the present specification, the absorption coefficient obtained based on the above-described rectangular cut piece 11a serving as a measurement target is defined as the absorption coefficient of GaAs single crystal substrate 1 for the near-infrared light having the wavelength of 1 micron. It should be noted that each of the above-described formulas 1 and 2 in consideration of multiple reflections is to determine a convergence value of an infinite geometric series under such an assumption that the near-infrared light undergoes an infinite number of times of reflections.

### <Dislocation Density>

GaAs single crystal substrate 1 may have a dislocation density of 1000 cm⁻² or less. GaAs single crystal substrate 1 may have a dislocation density of 500 cm⁻² or less. In particular, when GaAs single crystal substrate 1 at least includes Si as the n type dopant and has an atomic concentration of the Si of 2.0×10¹⁸ cm⁻³ or more, GaAs single crystal substrate 1 may have a dislocation density of 100 cm⁻² or less. In this case, GaAs single crystal substrate 1 may have a dislocation density of less than 100 cm⁻², or may have a dislocation density of 50 cm⁻² or less. Thus, with the low dislocation density, GaAs single crystal substrate 1 having an excellent optical property can be provided.

In the present specification, the “dislocation density” means an etch pit density (EPD) measured by the following method. That is, the “dislocation density” means the number of corrosion holes (etch pits) formed in main surface 11 per cm² in an etching test in which GaAs single crystal substrate 1 is immersed in molten potassium hydroxide at 500° C. for 10 minutes. A method of measuring the EPD is generally as follows. First, GaAs single crystal substrate 1 to serve as a measurement target is obtained based on the below-described production method, for example. Next, the main surface (for example, main surface 11) of GaAs single crystal substrate 1 is mirror-polished and GaAs single crystal substrate 1 is then immersed in a potassium hydroxide (KOH) melt at 500° C. for 10 minutes, thereby forming the etch pits in main surface 11. Here, in order to clearly show the etch pits, the mirror-polished main surface 11 may be subjected to at least one of a pretreatment using sulfuric acid and hydrogen peroxide and a pretreatment using ammonia water and hydrogen peroxide, before being immersed in the potassium hydroxide (KOH) melt for 10 minutes. Although the definition of the etch pit density is not academically the same as the definition of the dislocation density, the etch pit density is understood as being equivalent (industrial intermediate index) to the dislocation density in the present technical field.

Further, main surface 11 of GaAs single crystal substrate 1 taken out from the potassium hydroxide melt is divided in accordance with a grid formed by laying out squares each having a size of 5 mm×5 mm on the whole of main surface 11 such that the largest number of the squares are arranged side by side without overlapping each other. For example, the grid is formed by directly writing the grid on the substrate using a pen or the like. Then, each square of the grid on main surface 11 is defined as one visual field, and the number of etch pits present in the one visual field is counted by using a known optical microscope (for example, product name: ECLIPSE (registered trademark) LV150N provided by Nikon). Finally, the number of etch pits present in each visual field is converted into the number thereof per cm². Thus, since the same number of the numbers of etch pits per cm² as the number of squares of the grid is obtained, a value obtained by dividing the total of the numbers of etch pits per cm² by the number of the squares is determined as the EPD of GaAs single crystal substrate 1, that is, the dislocation density. It should be noted that when each of the outer periphery of main surface 11 and the outside thereof appear in the above-described visual field, this visual field is excluded from the target for calculating the EPD. This is because the fluctuation of the number of etch pits in a region in the vicinity of the outer periphery of GaAs single crystal substrate 1 is large among substrates and this region is normally a region that is not used as a material of an optical device.

### <Purpose of Use>

GaAs single crystal substrate 1 according to the present embodiment can be used as a substrate for an optical device such as a semiconductor laser (for example, a vertical cavity surface emitting laser, a light receiving element, or the like). Particularly, based on the feature described above, GaAs single crystal substrate 1 can be used as a substrate of an optical device intended to be used in an environment in which the optical device is likely to be exposed to radiation, such as a space environment.

### [Method of Producing GaAs Single Crystal]

The method of producing the GaAs single crystal according to the present embodiment may be, for example, a method of producing a GaAs single crystal used for the GaAs single crystal substrate described above. That is, the production method may be a method of producing a GaAs single crystal having n type conductivity using a vertical boat method. The production method includes: a step of preparing a single crystal growth apparatus at least including a crucible having a cylindrical shape and a heating apparatus disposed to surround an outer periphery of the crucible; a step of accommodating a seed crystal at a bottom portion of the crucible and accommodating an n type dopant, B₂O₃, metal arsenic (As), and a GaAs polycrystal in a form of a bulk or powder above the seed crystal in the crucible, the seed crystal being composed of the GaAs single crystal; and a step of heating the crucible using the heating apparatus to sublimate the metal As, melt the B₂O₃ into a B₂O₃ melt, melt a part of the seed crystal and the GaAs polycrystal into a GaAs melt, obtain a first melt in which the n type dopant is dissolved in the GaAs melt, and bring the first melt into contact with a remainder of the seed crystal; and a step of obtaining the GaAs single crystal by growing a crystal from the first melt on the remainder of the seed crystal. Hereinafter, the upward direction and downward direction along the axis of the crucible will be also simply referred to as the upward direction and the downward direction, and when describing a position or arrangement of a configuration, a position in the upward direction will be also referred to as an upper portion, and a position in the downward direction will be also referred to as a lower portion.

The single crystal growth apparatus includes a branch pipe portion (hereinafter, also referred to as “As partial pressure control portion”) that controls a partial pressure of As in the crucible. In the step of obtaining the GaAs single crystal, the end surface of the first melt not in contact with the remainder of the seed crystal is covered with the B₂O₃ melt by 10 area % or more and 50 area % or less. In the step of obtaining the GaAs single crystal, the GaAs in the first melt has an atomic ratio of As to Ga greater than 1. In particular, in the step of obtaining the GaAs single crystal in the method of producing the GaAs single crystal, the crucible may not be rotated, and the first melt may not be stirred.

According to the method of producing the GaAs single crystal according to the present embodiment, in the process of producing the GaAs single crystal using the vertical boat method, the GaAs single crystal is produced by controlling an amount of addition of the n type dopant, the partial pressure of the As in the crucible, or the like such that the activation ratio of the n type dopant in the GaAs single crystal becomes about 50%. In particular, in the process of producing the GaAs single crystal, the end surface of the first melt not in contact with the remainder of the seed crystal is covered with the B₂O₃ melt by 10 area % or more and 50 area % or less. Further, since the partial pressure of the As in the crucible is controlled in the As partial pressure control portion provided in the single crystal growth apparatus to dissolve, in the first melt, a necessary amount of metal As precipitated after the sublimation, with the result that the GaAs in the first melt has the atomic ratio of As to Ga greater than 1. When the end surface is completely covered with the B₂O₃ melt, the partial pressure of the As cannot be controlled by the As partial pressure control portion provided in the single crystal growth apparatus. When the end surface is not covered with the B₂O₃ melt at all, the partial pressure of the As can be controlled by the As partial pressure control portion, but B for improving the crystal strength is not added. According to the method of producing the GaAs single crystal according to the present embodiment, the partial covering of the end surface with the B₂O₃ melt and the control for the partial pressure of the As are simultaneously performed, with the result that the positions of occupation of the Si and the B in each of the first melt and the GaAs single crystal can be controlled and the addition concentrations thereof can be increased, thereby reducing the knock-on of atoms due to exposure to radiation. According to the production method having such a feature, the GaAs single crystal in which deterioration of performance due to exposure to radiation or the like can be reduced can be obtained.

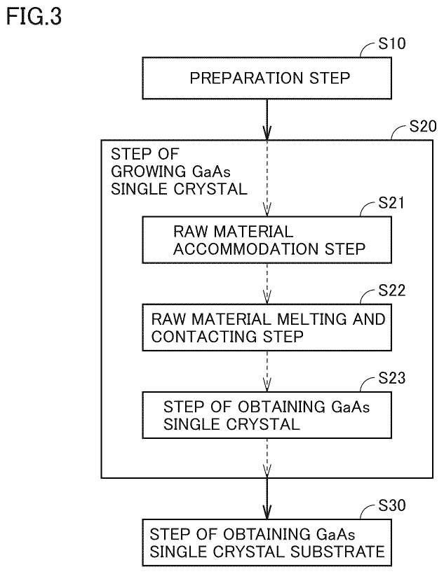

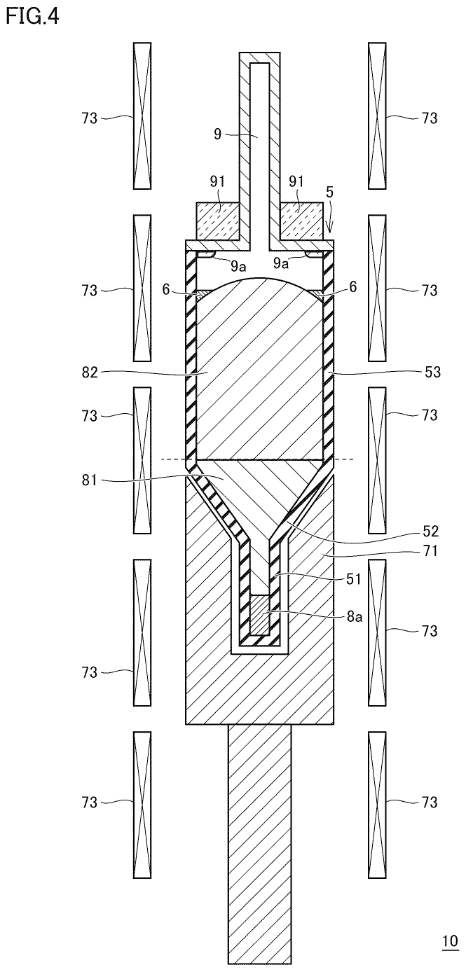

Hereinafter, the method of producing the GaAs single crystal according to the present embodiment and the method of producing the GaAs single crystal substrate including the same will be specifically described with reference to FIGS. 3 to 4. FIG. 3 is a flowchart showing an overview of each of the method of producing the GaAs single crystal according to the present embodiment and the method of producing the GaAs single crystal substrate including the same. FIG. 4 is an explanatory diagram illustrating the step of growing the GaAs single crystal using the single crystal production apparatus with regard to the method of producing the GaAs single crystal according to the embodiment.

In the method of producing the GaAs single crystal having the n type conductivity according to the present embodiment, the vertical boat method is used. Examples of the vertical boat method include a Vertical Bridgman (VB) method, a vertical gradient freeze (VGF) method, a hybrid method in which the VB method and the VGF method are combined, and the like. Hereinafter, the method of producing the GaAs single crystal using, for example, the VB method will be described. The production method is a method of producing a GaAs single crystal using, for example, the VB method, and may include: a step (preparation step) S10 of preparing a single crystal growth apparatus at least including a crucible having a cylindrical shape and a heating apparatus disposed to surround an outer periphery of the crucible; and a step S20 of growing the GaAs single crystal by crystal growth from a seed crystal using the single crystal growth apparatus, as shown in FIG. 3.

Step S20 of growing the GaAs single crystal includes: a step (raw material accommodation step) S21 of accommodating a seed crystal at a bottom portion of the crucible and accommodating an n type dopant, B₂O₃, metal As, and a GaAs polycrystal in the form of a bulk or powder above the seed crystal in the crucible, the seed crystal being composed of the GaAs single crystal; a step (raw material melting and contacting step) S22 of heating the crucible using the heating apparatus to sublimate the metal As, melt the B₂O₃ into a B₂O₃ melt, melt a part of the seed crystal and the GaAs polycrystal into a GaAs melt, obtain a first melt in which the n type dopant is dissolved in the GaAs melt, and bring the first melt into contact with the remainder of the seed crystal; and a step (step of obtaining the GaAs single crystal) S23 of obtaining the GaAs single crystal by growing the crystal on the remainder of the seed crystal from the first melt.

Referring to FIG. 3, the below-described method of producing the GaAs single crystal substrate according to the present embodiment may be constructed from preparation step S10, step S20 of growing the GaAs single crystal, each of which is a step included in the foregoing production method, and a step S30 of obtaining the GaAs single crystal substrate by processing the GaAs single crystal obtained by the foregoing production method.

### <Preparation Step>

In the step (preparation step) S10 of preparing the single crystal growth apparatus, for example, a single crystal growth apparatus 10 including a crucible 5 and a heating apparatus 73 as shown in FIG. 4 is prepared. Further, in preparation step S10, in addition to single crystal growth apparatus 10, a seed crystal 8a serving as a material for growing a GaAs single crystal 81, metal As in the form of, for example, a bulk, and a GaAs polycrystal in the form of a bulk or powder are prepared. Seed crystal 8a is composed of a GaAs single crystal. Each of seed crystal 8a and the GaAs polycrystal may be prepared by a known method, or may be prepared by obtaining a commercially available product. Seed crystal 8a may have a columnar shape such that seed crystal 8a can be accommodated in a seed crystal accommodation portion 51 of crucible 5 as described later. The GaAs polycrystal may have such a size that GaAs polycrystal can be accommodated at least in a straight barrel portion 53 of crucible 5 as described later.

### (Single Crystal Growth Apparatus)

### 1) Crucible

As shown in FIG. 4, single crystal growth apparatus 10 includes crucible 5. Crucible 5 may include: seed crystal accommodation portion 51 having a cylindrical shape to accommodate seed crystal 8a composed of a GaAs single crystal; an increased-diameter portion 52 connected to seed crystal accommodation portion 51; and straight barrel portion 53 connected to increased-diameter portion 52. Seed crystal accommodation portion 51 has a hollow portion, the hollow portion being opened at a position connected to increased-diameter portion 52, the hollow portion being provided with a bottom wall formed at a position opposite to increased-diameter portion 52. Seed crystal accommodation portion 51 can accommodate and hold seed crystal 8a in the hollow portion. Increased-diameter portion 52 has a truncated conical shape having a diameter that is increased in the upward direction of crucible 5, and is connected to seed crystal accommodation portion 51 on the small-diameter side of increased-diameter portion 52. Straight barrel portion 53 has a hollow cylindrical shape and is connected to the large-diameter side of increased-diameter portion 52. Each of increased-diameter portion 52 and straight barrel portion 53 has a function of holding the GaAs polycrystal, which is a material for obtaining the GaAs single crystal 81 by crystal growth, therein. Each of increased-diameter portion 52 and straight barrel portion 53 has a function of growing the GaAs single crystal by solidifying the GaAs melt and first melt 82 including the n type dopant as described later. Crucible 5 can be composed of various materials that can endure the temperature of first melt 82. For example, the material of crucible 5 is pyrolytic boron nitride (PBN).

The maximum inner diameter of crucible 5 is 100 mm or more. More specifically, the inner diameter of straight barrel portion 53 of crucible 5 may be 100 mm or more. The inner diameter of straight barrel portion 53 of crucible 5 may be 150 mm or more. The upper limit of the maximum inner diameter of crucible 5 is not particularly limited, but is, for example, 210 mm.

### 2) Holding Base

Single crystal growth apparatus 10 includes a holding base 71 that holds increased-diameter portion 52 of crucible 5. Holding base 71 can have, for example, an appearance with a cylindrical shape. Holding base 71 may be composed of a single material. As the material, for example, quartz, alumina, silicon carbide, or the like can be employed. The material may be composed of quartz. In particular, the material may be non-transparent when heat conduction in each of the crucible and the GaAs melt is taken into consideration. The outer diameter of holding base 71 may correspond to or may be the same as the outer diameter of straight barrel portion 53.

### 3) Heating Apparatus

Single crystal growth apparatus 10 includes heating apparatus 73 that heats crucible 5. Heating apparatus 73 may consist of two apparatuses. In this case, these two apparatuses are disposed to surround the outer periphery of crucible 5. Each apparatus of heating apparatus 73 is divided into a plurality of portions in a direction perpendicular to the axis of the crucible. Thus, each apparatus of heating apparatus 73 is formed to have multiple stages. Further, an output of heating apparatus 73 can be independently controlled for each apparatus and for each portion. Hence, a temperature at a position of an interface between GaAs single crystal 81 and first melt 82 can be strictly controlled. As heating apparatus 73, for example, a known electric heater may be employed.

Single crystal growth apparatus 10 can include a thermocouple that can measure the temperature of crucible 5 heated by heating apparatus 73. A plurality of the thermocouples may be disposed outside crucible 5 along the axial direction thereof. In this case, the plurality of thermocouples may be disposed outside crucible 5 at least at a height approximately corresponding to the interface between GaAs single crystal 81 and first melt 82 in crucible 5 in the axial direction of crucible 5. Based on the temperatures measured by the thermocouples, the temperatures of respective portions of GaAs single crystal 81 grown in crucible 5 are estimated. In particular, a temperature distribution in the radial direction at the interface can be estimated based on the respective temperatures measured by the thermocouples.

### 4) Branch Pipe Portion (As Partial Pressure Control Portion)

Single crystal growth apparatus 10 includes an As partial pressure control portion 9 that controls the partial pressure of the As in crucible 5. For example, As partial pressure control portion 9 is disposed at a position opposite to seed crystal accommodation portion 51 in the axial direction. As partial pressure control portion 9 controls the partial pressure of the As in crucible 5 in step S23 of obtaining the GaAs single crystal. Specifically, due to the function of As partial pressure control portion 9, the temperature in crucible 5 is controlled to be lowest in As partial pressure control portion 9 in step S23 of obtaining the GaAs single crystal. As a result, a metal As 9a, which is sublimated and precipitated on the side wall, the upper wall, or the like of crucible 5 in response to the heating of crucible 5 in raw material melting and contacting step S22, is dissolved in first melt 82 by such an amount that the pressure of the As becomes 101 kPa at, for example, 1238° C. in step S23 of obtaining the GaAs single crystal. On this occasion, the atomic ratio of each of the As in first melt 82 including the GaAs melt and GaAs single crystal 81 is such that the As is more than 1 with respect to the Ga. As shown in FIG. 4, in order to contribute to the temperature control in crucible 5 by As partial pressure control portion 9, a heat insulating material 91 may be disposed adjacent to As partial pressure control portion 9. For heat insulating material 91, for example, a known heat insulating material used for temperature control of a crucible or the like in the vertical boat method can be employed. Thus, the n type dopant in first melt 82 is facilitated to be introduced into the Ga site in the crystal lattice of the GaAs single crystal, with the result that the activation ratio of the n type dopant can be controlled. As partial pressure control portion 9 can be composed of, for example, the same material as that of crucible 5.

### <Step of Growing GaAs Single Crystal>

Next, in the above-described production method, step S20 of growing the GaAs single crystal by the crystal growth from the seed crystal using the above-described single crystal growth apparatus is performed. Specifically, in step S20 of growing the GaAs single crystal, single crystal growth apparatus 10 and seed crystal 8a described above are used to grow GaAs single crystal 81. Step S20 of growing the GaAs single crystal includes raw material accommodation step S21, raw material melting and contacting step S22, and step S23 of obtaining the GaAs single crystal, as described below. These steps are performed in this order in step S20 of growing the GaAs single crystal.

### (Raw Material Accommodation Step)

In raw material accommodation step S21, seed crystal 8a composed of the GaAs single crystal is accommodated in the hollow portion of seed crystal accommodation portion 51 of crucible 5. As a method of accommodating seed crystal 8a in seed crystal accommodation portion 51, a known method is used, for example. Moreover, a plurality of the GaAs polycrystals are accommodated and stacked in increased-diameter portion 52 and straight barrel portion 53 of crucible 5. The metal As for controlling the pressure of the arsenic, and at least one selected from the group consisting of Si, Te, and Sn as the n type dopant are added to increased-diameter portion 52 and straight barrel portion 53 in crucible 5 together with each of the GaAs polycrystals. Further, solid B₂O₃ is accommodated on the GaAs polycrystal. In this case, the n type dopant may be added by such an amount that the atomic concentration thereof in GaAs single crystal 81 obtained by the crystal growth is 5.8×10¹⁸ cm⁻³ or more and 1.3×10¹⁹ cm⁻³ or less. The solid B₂O₃ may be accommodated by such an amount that the end surface of first melt 82 not in contact with the remainder of seed crystal 8a is covered with B₂O₃ melt 6 by 10 area % or more and 50 area % or less when the solid B₂O₃ is melted into B₂O₃ melt 6 in the below-described step S23 of obtaining the GaAs single crystal.

### (Raw Material Melting and Contacting Step)

In raw material melting and contacting step S22, in order to obtain GaAs single crystal 81, seed crystal 8a and first melt 82 in which the n type dopant is dissolved in the GaAs melt are brought into contact with each other. In raw material melting and contacting step S22, crucible 5 in which seed crystal 8a, the GaAs polycrystal, the n type dopant, the metal As, and the solid B₂O₃ are accommodated is supported by holding base 71. Thereafter, current is supplied to heating apparatus 73 so as to heat crucible 5. Thus, the GaAs polycrystal is melted and the n type dopant is dissolved therein, thereby forming first melt 82. The metal As in the form of a bulk and disposed in the vicinity of the GaAs polycrystal is sublimated. Thereafter, metal As 9a is precipitated on the side wall, upper wall, or the like of crucible 5, each of which has a low temperature in crucible 5. Further, a part of seed crystal 8a is also melted, and the remainder of seed crystal 8a and first melt 82 are brought into contact with each other at an interface therebetween. The solid B₂O₃ is also melted into B₂O₃ melt 6. B₂O₃ melt 6 is located on an upper part of first melt 82 due to a difference in specific gravity.

### (Step of Obtaining GaAs Single Crystal)

In step S23 of obtaining the GaAs single crystal, for example, crucible 5 is gradually pulled downward (to the seed crystal accommodation portion 51 side) with respect to heating apparatus 73, thereby forming a temperature gradient in which the temperature on the seed crystal 8a side is low and the temperature on the first melt 82 side is high in crucible 5. Thus, first melt 82 in contact with seed crystal 8a is solidified, with the result that GaAs single crystal 81 is continuously crystal-grown from first melt 82 on the remainder of seed crystal 8a. A speed of pulling crucible 5 downward is not particularly limited, but is, for example, 1 to 5 mm/hour.

In step S23 of obtaining the GaAs single crystal, the end surface of first melt 82 not in contact with the remainder of seed crystal 8a is covered with B₂O₃ melt 6 by 10 area % or more and 50 area % or less. Specifically, in a state in which first melt 82 is heated by heating apparatus 73, the end surface thereof has a shape protruding in the upward direction and the top portion of the end surface is exposed from B₂O₃ melt 6. Thus, only a peripheral portion around the top portion is covered with B₂O₃ melt 6. The description “the end surface is covered with B₂O₃ melt 6 by 10 area % or more and 50 area % or less” means that in the end surface, the peripheral portion is 10 area % or more and 50 area % or less and the top portion is 50 area % or more and 90 area % or less.

Further, in step S23 of obtaining the GaAs single crystal, the As in first melt 82 is controlled via the top portion of 50 area % or more and 90 area % or less, which is not covered with B₂O₃ melt 6 at the end surface. Specifically, since the temperature of As partial pressure control portion 9 is the lowest temperature in crucible 5, the pressure of As corresponding to the temperature of As partial pressure control portion 9 is exerted toward the end surface of first melt 82. Thus, among metal As 9a precipitated on the side wall, upper wall, or the like of crucible 5 as described above, an amount of metal As 9a by which the pressure of the arsenic is 101 kPa at 1238° C. by the function of As partial pressure control portion 9 is dispersed in crucible 5, and is dissolved in first melt 82. The GaAs in first melt 82 has the atomic ratio of As to Ga greater than 1, and the n type dopant in first melt 82 is facilitated to be introduced into the Ga site in the crystal lattice of GaAs single crystal 81, with the result that the activation ratio of the n type dopant can be controlled.

In step S23 of obtaining the GaAs single crystal, crucible 5 is pulled downward with respect to heating apparatus 73, with the result that the crystal growth of GaAs single crystal 81 is continued until the solidification of first melt 82 remaining in straight barrel portion 53 of crucible 5 is completed. Here, in step S23 of obtaining the GaAs single crystal, crucible 5 need not be rotated and first melt 82 need not be stirred from the viewpoint of causing the B, which is a light element in first melt 82, to stay at the upper part of first melt 82 by gravity segregation. This is due to the following reason: when the concentration of the B introduced into first melt 82 from B₂O₃ melt 6 is increased too much, boron arsenide is precipitated in first melt 82, which may deteriorate the crystallinity of GaAs single crystal 81. Thus, the atomic concentration of the B in GaAs single crystal 81 can be controlled to be 4.0×10¹⁸ cm⁻³ or more and 6.0×10¹⁸ cm⁻³ or less. In this way, GaAs single crystal 81 (for example, an ingot thereof) is obtained. GaAs single crystal 81 in crucible 5 is then taken out from crucible 5.

### [Method of Producing GaAs Single Crystal Substrate]

### <Step S30 of Obtaining GaAs Single Crystal Substrate>

The method of producing the GaAs single crystal substrate according to the present embodiment is a method of producing a GaAs single crystal substrate having n type conductivity. As shown in FIG. 3, the production method includes step S30 of obtaining the GaAs single crystal substrate having the main surface having the circular shape by processing the GaAs single crystal obtained by the method of producing the GaAs single crystal. Specifically, step S30 of obtaining the GaAs single crystal substrate includes: a cutting step of obtaining a GaAs single crystal substrate precursor by cutting GaAs single crystal 81 obtained by the above-described method of producing the GaAs single crystal into the disk shape; and an outer periphery grinding step of obtaining the GaAs single crystal substrate having the main surface having the circular shape by processing the outer periphery of the GaAs single crystal substrate precursor by grinding or the like. According to the production method having such a feature, the deterioration of performance due to exposure to radiation or the like is reduced, thereby obtaining the GaAs single crystal substrate suitable as a substrate of an optical device assumed to be used in a space environment.

Step S30 of obtaining the GaAs single crystal substrate includes the following cutting step, outer peripheral grinding step, and, as necessary, a polishing step described later, and these steps may be performed in this order.

The cutting step is a step of slicing the ingot into a wafer having a predetermined thickness in order to obtain the GaAs single crystal substrate precursor having the disk shape from the ingot formed from GaAs single crystal 81 taken out from crucible 5. Further, the outer periphery grinding step is a step of obtaining the GaAs single crystal substrate having the main surface having the circular shape by grinding the outer periphery of the GaAs single crystal substrate precursor. For the cutting step and the outer periphery grinding step, a known cutting method and a known outer periphery grinding method may be used. Further, the polishing step is a step of forming the main surface into a mirror surface. For the polishing step, a known polishing method may be used.

### Examples

Hereinafter, the present disclosure will be described more in detail with reference to examples, but the present disclosure is not limited thereto. In the present example, the present inventors have used a single crystal growth apparatus such as the one shown in FIG. 4 so as to perform crystal growth of a GaAs single crystal in accordance with the VB method with the <100> direction being set as the growth direction. In the following description, samples 1 to 4 correspond to examples of the present disclosure, and samples A and B correspond to comparative examples.

### [Production of GaAs Single Crystal Substrate]

### <Sample 1>

### (Preparation Step)

First, the single crystal growth apparatus such as the one shown in FIG. 4 was prepared. Further, a GaAs seed crystal composed of a GaAs single crystal and a GaAs polycrystal in the form of a bulk were prepared by a known method. The GaAs seed crystal had a columnar shape such that the GaAs seed crystal could be accommodated in the seed crystal accommodation portion of the crucible. The GaAs polycrystal had such a size that the GaAs polycrystal could be accommodated in the straight barrel portion. The inner diameter of the straight barrel portion of the crucible included in the single crystal growth apparatus was 154 mm.

### (Step of Growing GaAs Single Crystal)

The step of growing the GaAs single crystal by the crystal growth from the GaAs seed crystal using the single crystal growth apparatus was performed by performing the above-described raw material accommodation step, the above-described raw material melting and contacting step, and the above-described step of obtaining the GaAs single crystal. In the raw material accommodation step, Si was added into the crucible together with the GaAs polycrystal, as an n type dopant at an atomic concentration of 7.0×10¹⁸ cm⁻³. Further, for the purpose of controlling a pressure of arsenic, metal As was disposed by such an amount that the pressure of the arsenic at 1238° C. was 101 kPa in the volume inside the crucible. Moreover, 10 g of solid B₂O₃ was accommodated in the crucible. In the raw material melting and contacting step, the entire amount of the metal As was sublimated. In the step of obtaining the GaAs single crystal, the peripheral portion corresponding to 10 area % of the end surface of the first melt, in which the n type dopant was dissolved in the GaAs melt, not in contact with the GaAs seed crystal was covered with the B₂O₃ melt. Here, when the temperature of the first melt not covered with the B₂O₃ is defined as T1, the pressure of the arsenic in equilibrium with the GaAs (first melt) at temperature T1 is defined as P1, the temperature of the branch pipe portion is defined as T2, and the vapor pressure of the metal As in the branch pipe portion at temperature T2 is defined as P2, vapor pressure P2 of the metal As becomes larger as temperature T2 of the branch pipe portion is higher. In accordance with the above-described fact, temperature T2 of the branch pipe portion was adjusted to be the lowest temperature in the crucible at the point of time when the entire amount of the GaAs was melted in the step of obtaining the GaAs single crystal, thereby controlling the partial pressure of the As in the crucible. Thus, the atomic ratio of the GaAs in the first melt was such that the As was more than 1 with respect to the Ga. For example, pressure of arsenic P1 in equilibrium with the GaAs at 1238° C. is about 91 kPa in total of As4, which is a four-atom molecule of As, and As2, which is a two-atom molecule of As. In this case, when temperature T2 of the branch pipe portion is 613° C., vapor pressure P2 of the metal As becomes 101 kPa. That is, since P2>P1, the As is more than 1 with respect to the Ga in the atomic ratio of the GaAs in the first melt.

In the step of obtaining the GaAs single crystal, the speed at which the crucible was gradually pulled downward with respect to the heating apparatus was set to 4 mm/hour. Thereafter, crystal growth of the GaAs single crystal was continued until solidification of the melt remaining in the straight barrel portion of the crucible was completed. In this way, a GaAs single crystal ingot having a diameter of 154 mm and a thickness of 200 mm was produced.

### (Step of Obtaining GaAs Single Crystal Substrate)

A required number of GaAs single crystal substrates of a sample 1 each having n type conductivity and a main surface having a circular shape were produced from the above-described GaAs single crystal ingot by performing the above-described step of obtaining the GaAs single crystal substrate. Each of the GaAs single crystal substrates of sample 1 had a diameter of 150 mm and a thickness of 650 μm.

### <Samples 2 to 4>

A required number of GaAs single crystal substrates of each of samples 2 to 4 were produced in the same manner as in the production method of obtaining the GaAs single crystal substrate of sample 1, except that an amount of the Si added as the n type dopant in the raw material accommodation step was changed as described in Table 1.

### <Sample A>

A known horizontal Bridgman method (HB method) was used to produce each of GaAs single crystal substrates of a sample A. In this case, the atomic concentration of the Si serving as the n type dopant added to the GaAs melt was as described in Table 1. Moreover, B₂O₃ was not used in the production of the GaAs single crystal substrate of sample A.

### <Sample B>

A required number of GaAs single crystal substrates of a sample B were produced in the same manner as in the production method of obtaining the GaAs single crystal substrate of sample 1, except that the amount of the Si added as the n type dopant in the raw material accommodation step was changed as described in Table 1, the whole of the end surface of the first melt in which the n type dopant was dissolved in the GaAs melt was covered with the B₂O₃ melt in the step of obtaining the GaAs single crystal, and the partial pressure of the As in the crucible was not intentionally controlled at the As partial pressure control portion.

### [Evaluation on Properties of GaAs Single Crystal Substrate]

For each of the GaAs single crystal substrates of samples 1 to 4, A, and B, the above-described measurement methods and calculation methods were used to determine the atomic concentration of the Si, the atomic concentration of the B, the carrier concentration, the activation ratio, the dislocation density (EPD), the absorption coefficients for the infrared light having the wavelength of 1 micron before and after the electron beam irradiation, and the absorption coefficient ratio (the absorption coefficient for the infrared light having the wavelength of 1 micron after the electron beam irradiation/the absorption coefficient for the infrared light having the wavelength of 1 micron before the electron beam irradiation×100). The results are shown in Table 1.

TABLE 1

| | Sample A | Sample B | Sample 1 | Sample 2 | Sample 3 | Sample 4 |
|---|---|---|---|---|---|---|
| Carrier Concentration | 1.0 × 10¹⁸ | 1.0 × 10¹⁸ | 3.8 × 10¹⁸ | 3.7 × 10¹⁸ | 4.8 × 10¹⁸ | 4.6 × 10¹⁸ |
| (cm⁻³) | | | | | | |
| Silicon (Si) Concentration | 1.2 × 10¹⁸ | 1.3 × 10¹⁸ | 7.0 × 10¹⁸ | 7.6 × 10¹⁸ | 9.8 × 10¹⁸ | 9.8 × 10¹⁸ |
| (cm⁻³) | | | | | | |
| Boron (B) Concentration | NC | 1.2 × 10¹⁸ | 4.0 × 10¹⁸ | 5.0 × 10¹⁸ | 6.0 × 10¹⁸ | 6.0 × 10¹⁸ |
| (cm⁻³) | | | | | | |
| Activation Ratio | 83.3 | 76.9 | 54.3 | 48.7 | 51.0 | 46.9 |
| (n Type, %) | | | | | | |
| EPD | 1000 | 100 | 50 | 10 | 20 | 20 |
| (cm⁻²) | | | | | | |
| Infrared Light Absorption | 5.2 | 5.0 | 4.4 | 4.2 | 3.6 | 3.7 |
| Coefficient | | | | | | |
| (Before Electron Beam | | | | | | |
| Irradiation, cm⁻¹) | | | | | | |
| Infrared Light Absorption | 4.4 | 4.6 | 4.2 | 4.1 | 3.6 | 3.7 |
| Coefficient | | | | | | |
| (After Electron Beam | | | | | | |
| Irradiation, cm⁻¹) | | | | | | |
| Absorption Coefficient | 84.6 | 92.0 | 95.5 | 97.6 | 100 | 100 |
| Ratio (%) | | | | | | |

### [Review]

According to Table 1, it is understood that in comparison with samples A and B, the absorption coefficient ratio for the infrared light having the wavelength of 1 micron before and after the electron beam irradiation is 95 to 100% in each of the GaAs single crystal substrates of samples 1 to 4, and therefore, the deterioration of performance due to exposure to radiation or the like is reduced. Therefore, it is suggested that each of the GaAs single crystal substrates of samples 1 to 4 can be a substrate of an optical device assumed to be used in a space environment.

Heretofore, the embodiments and examples of the present disclosure have been illustrated, but it has been initially expected to appropriately combine configurations of the embodiments and examples.

The embodiments of the present invention have been described but the embodiments disclosed herein are illustrative and non-restrictive in any respect. The scope of the present invention is defined by the terms of the claims, and is intended to include any modifications within the scope and meaning equivalent to the terms of the claims.

What is claimed is:

1. A gallium arsenide single crystal substrate having electron-donating type conductivity, wherein
the gallium arsenide single crystal substrate has main surfaces each having a circular shape,
the gallium arsenide single crystal substrate includes an electron-donating type dopant, and
a value of an absorption coefficient of the gallium arsenide single crystal substrate for infrared light having a wavelength of 1 micron as obtained by performing measurement after performing electron beam irradiation on at least one of the main surfaces under a condition of an acceleration voltage of 2 MeV and an irradiation dose of 150 kGy is 95% or more and 100% or less of a value of an absorption coefficient of the gallium arsenide single crystal substrate for infrared light having a wavelength of 1 micron as obtained by performing measurement before performing the electron beam irradiation.

2. The gallium arsenide single crystal substrate according to claim 1, wherein
the gallium arsenide single crystal substrate has a carrier concentration of 3.5×10¹⁸ cm⁻³ or more and 5.0×10¹⁸ cm⁻³ or less, and
the gallium arsenide single crystal substrate has an activation ratio of the electron-donating type dopant of 40% or more and 60% or less.

3. The gallium arsenide single crystal substrate according to claim 2, wherein the gallium arsenide single crystal substrate has an activation ratio of the electron-donating type dopant of 45% or more and 55% or less.

4. The gallium arsenide single crystal substrate according to claim 1, wherein the gallium arsenide single crystal substrate has an atomic concentration of the electron-donating type dopant of 5.8×10¹⁸ cm⁻³ or more and 1.3×10¹⁹ cm⁻³ or less.

5. The gallium arsenide single crystal substrate according to claim 1, wherein
the gallium arsenide single crystal substrate includes boron, and
the gallium arsenide single crystal substrate has an atomic concentration of the boron of 4.0×10¹⁸ cm⁻³ or more and 6.0×10¹⁸ cm⁻³ or less.

6. The gallium arsenide single crystal substrate according to claim 1, wherein the value of the absorption coefficient of the gallium arsenide single crystal substrate for the infrared light having the wavelength of 1 micron as obtained by performing the measurement before performing the electron beam irradiation is 3.6 cm⁻¹ or more.

7. The gallium arsenide single crystal substrate according to claim 1, wherein the electron-donating type dopant is at least one selected from a group consisting of silicon, tellurium, and tin.

8. The gallium arsenide single crystal substrate according to claim 1, wherein the gallium arsenide single crystal substrate has a dislocation density of 1000 cm⁻² or less.

9. The gallium arsenide single crystal substrate according to claim 8, wherein
the gallium arsenide single crystal substrate at least includes silicon as the electron-donating type dopant,
the gallium arsenide single crystal substrate has an atomic concentration of the silicon of 2.0×10¹⁸ cm⁻³ or more, and
the gallium arsenide single crystal substrate has the dislocation density of 100 cm⁻² or less.

10. A method of producing a gallium arsenide single crystal having electron-donating type conductivity using a vertical boat method, the method of producing the gallium arsenide single crystal comprising:
preparing a single crystal growth apparatus at least including a crucible having a cylindrical shape and a heating apparatus disposed to surround an outer periphery of the crucible;
accommodating a seed crystal at a bottom portion of the crucible and accommodating an electron-donating type dopant, boron oxide, metal arsenic, and a gallium arsenide polycrystal in a form of a bulk or powder above the seed crystal in the crucible, the seed crystal being composed of the gallium arsenide single crystal;
heating the crucible using the heating apparatus to sublimate the metal arsenic, melt the boron oxide into a boron oxide melt, melt a part of the seed crystal and the gallium arsenide polycrystal into a gallium arsenide melt, obtain a first melt in which the electron-donating type dopant is dissolved in the gallium arsenide melt, and bring the first melt into contact with a remainder of the seed crystal; and
obtaining the gallium arsenide single crystal by growing a crystal from the first melt on the remainder of the seed crystal, wherein
the single crystal growth apparatus includes a branch pipe portion that controls a partial pressure of arsenic in the crucible,
in the obtaining the gallium arsenide single crystal, an end surface of the first melt not in contact with the remainder of the seed crystal is covered with the boron oxide melt by 10 area % or more and 50 area % or less, and
in the obtaining the gallium arsenide single crystal, the gallium arsenide in the first melt has an atomic ratio of arsenic to gallium greater than 1.

11. The method of producing the gallium arsenide single crystal according to claim 10, wherein in the obtaining the gallium arsenide single crystal, the crucible is not rotated and the first melt is not stirred.

12. A method of producing a gallium arsenide single crystal substrate, the method comprising obtaining a gallium arsenide single crystal substrate having a main surface having a circular shape by processing the gallium arsenide single crystal obtained by the method of producing the gallium arsenide single crystal according to claim 10.
